(19) United States
(12) Patent Application Publication
(10) Pub. No.: US 2025/0311394 A1
(43) Pub. Date: Oct. 2, 2025

(54) SEMICONDUCTOR DEVICE AND METHOD OF MANUFACTURING THE SAME

(71) Applicant: Renesas Electronics Corporation, Tokyo (JP)

(72) Inventors: Makoto KOSHIMIZU, Tokyo (JP); Masato SAKURAI, Tokyo (JP)

(21) Appl. No.: 19/069,346

(22) Filed: Mar. 4, 2025

(30) Foreign Application Priority Data
Apr. 1, 2024 (JP) 2024-059217

(51) Int. Cl. H10D 84/40; G05F 3/26; H10D 84/01

(52) U.S. Cl. CPC H10D 84/401; H10D 84/0109; G05F 3/265

(57) ABSTRACT

An n-type impurity region is formed in a semiconductor substrate. A p-type well region and an n-type collector region are formed in the impurity region. An n-type emitter region and a p-type base region are formed in the well region. When a distance from a first junction surface to a second junction surface is Wb1, an impurity concentration of a part of the well region located under the first junction surface is Na1, a distance from a third junction surface to the base region is Wb2, and an impurity concentration of a part of the well region located between the third junction surface and the base region is Na2, the relationship (Na1×Wb1)≤(Na2×Wb2) is satisfied.

### CROSS-REFERENCE TO RELATED APPLICATIONS

The disclosure of Japanese Patent Application No. 2024-059217 filed on Apr. 1, 2024, including the specification, drawings and abstract is incorporated herein by reference in its entirety.

### BACKGROUND

The present invention relates to a semiconductor device and a method of manufacturing the same.

There are disclosed techniques listed below.

### [Patent Document 1] Japanese Unexamined Patent Application

Publication No. 2007-96154

In semiconductor devices including analog circuits, bipolar transistors or MISFETs (Metal Insulator Semiconductor Field Effect Transistors) are used. For example, Patent Document 1 discloses an NPN type bipolar transistor. In Patent Document 1, an n-type well region is formed in a semiconductor substrate, and a p-type well region is formed in the n-type well region. In the p-type well region, a p-type base region and an n-type emitter region are formed. Additionally, at a location spaced apart from the p-type well region in plan view, an n-type collector region is formed in the n-type well region.

The n-type well region and the n-type collector region function as the collector of the bipolar transistor. The p-type well region and the p-type base region function as the base of the bipolar transistor. The n-type emitter region functions as the emitter of the bipolar transistor.

### SUMMARY

In such a bipolar transistor as described above, the concentration of the shallow part of the p-type well region located near the upper surface of the semiconductor substrate may be reduced, and the concentration of the deep part of the p-type well region located under the shallow part may be increased. This makes it easier to prevent punch-throughs and to secure the breakdown voltage between the collector and the base.

However, due to the reduction in the concentration of the shallow part of the p-type well region, the base current IB tends to increase, making it easy for the current amplification factor hFE (=IC/IB) to decrease. Therefore, the performance of the bipolar transistor may degrade, and the performance of the semiconductor device may degrade.

Other problems and novel features will become apparent from the description of this specification and the accompanying drawings.

In one embodiment, a semiconductor device includes a semiconductor substrate, a first impurity region of a first conductivity type formed in the semiconductor substrate, a first well region of a second conductivity type formed in the first impurity region, an emitter region of the first conductivity type formed in the first well region, a base region of the second conductivity type formed in the first well region, and a collector region of the first conductivity type formed in the first impurity region. When a distance from a first junction surface between a lower surface of the emitter region and the first well region to a second junction surface between a lower surface of the first well region and the first impurity region is Wb1, an impurity concentration of the part of the first well region located under the first junction surface is Na1, a distance from a third junction surface between the side surface of the emitter region and the first well region to the base region is Wb2, and an impurity concentration of the part of the first well region located between the third junction surface and the base region is Na2, the relationship (Na1×Wb1)≤(Na2×Wb2) is satisfied.

In one embodiment, a manufacturing method of a semiconductor device includes preparing a semiconductor substrate including a first impurity region of a first conductivity type, forming a first well region of a second conductivity type in the first impurity region, forming a base region of the second conductivity type in the first well region, and forming an emitter region of the first conductivity type in the first well region and forming a collector region of the first conductivity type in the first impurity region. When a distance from a first junction surface between a lower surface of the emitter region and the first well region to a second junction surface between a lower surface of the first well region and the first impurity region is Wb1, an impurity concentration of the part of the first well region located under the first junction surface is Na1, a distance from a third junction surface between a side surface of the emitter region and the first well region to the base region is Wb2, and an impurity concentration of the part of the first well region located between the third junction surface and the base region is Na2, the relationship (Na1×Wb1)≤(Na2×Wb2) is satisfied.

According to the embodiment, the performance of the semiconductor device can be improved.

### BRIEF DESCRIPTION OF THE DRAWINGS

FIG. 1 is a plan view showing a semiconductor device in a first embodiment.

FIG. 2 is a cross-sectional view showing the semiconductor device in the first embodiment.

FIG. 3 is a diagram showing an impurity profile of the semiconductor device in the first embodiment.

FIG. 4 is an equivalent circuit diagram showing a current mirror circuit in the first embodiment.

FIG. 5 is a main portion cross-sectional view showing a part of a bipolar transistor in an examined example.

FIG. 6 is a main portion cross-sectional view showing a part of a bipolar transistor in the first embodiment.

FIG. 7 is an explanatory diagram explaining the main features of the bipolar transistor in the first embodiment.

FIG. 8 is a diagram showing data obtained in experiments conducted by the inventors.

FIG. 9 is a cross-sectional view showing the semiconductor device in the first embodiment.

FIG. 10 is a cross-sectional view showing a manufacturing step of the semiconductor device in the first embodiment.

FIG. 11 is a cross-sectional view showing a manufacturing step of the semiconductor device in the first embodiment.

FIG. 12 is a cross-sectional view showing a manufacturing step of the semiconductor device following FIG. 10.

FIG. 13 is a cross-sectional view showing a manufacturing step of the semiconductor device following FIG. 11.

FIG. 14 is a cross-sectional view showing a manufacturing step of the semiconductor device following FIG. 12.

FIG. 15 is a cross-sectional view showing a manufacturing step of the semiconductor device following FIG. 13.

FIG. 16 is a cross-sectional view showing a manufacturing step of the semiconductor device following FIG. 14.

FIG. 17 is a cross-sectional view showing a manufacturing step of the semiconductor device following FIG. 15.

FIG. 18 is a cross-sectional view showing a manufacturing step of the semiconductor device following FIG. 16.

FIG. 19 is a cross-sectional view showing a manufacturing step of the semiconductor device following FIG. 17.

FIG. 20 is a cross-sectional view showing a manufacturing step of the semiconductor device following FIG. 18.

FIG. 21 is a cross-sectional view showing a manufacturing step of the semiconductor device following FIG. 19.

FIG. 22 is a cross-sectional view showing a manufacturing step of the semiconductor device following FIG. 20.

FIG. 23 is a cross-sectional view showing a manufacturing step of the semiconductor device following FIG. 21.

FIG. 24 is a main portion cross-sectional view showing a part of a bipolar transistor in a first modified example.

FIG. 25 is a main portion cross-sectional view showing a part of a bipolar transistor in a second modified example.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. Furthermore, in the following embodiments, descriptions of the same or similar parts will not be repeated in principle except when particularly necessary.

Furthermore, the X direction, Y direction, and Z direction described in this application intersect each other and are orthogonal to each other. In this application, the Z direction is described as the vertical direction, depth direction, or thickness direction of a certain structure. Moreover, expressions such as “plan view” or “planar view” used in this application mean a plane configured by the X and Y directions, and viewing this “plane” from the Z direction.

### First Embodiment

### Structure of Bipolar Transistor

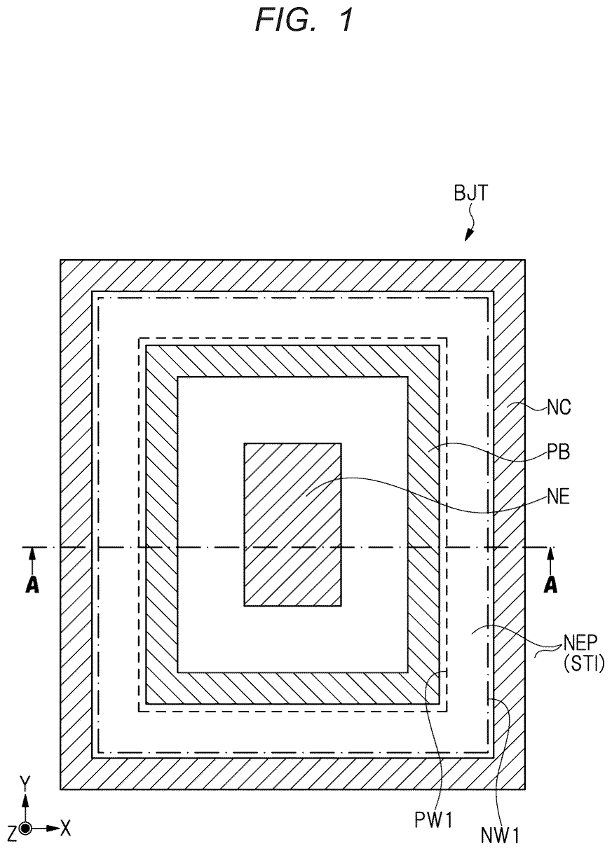

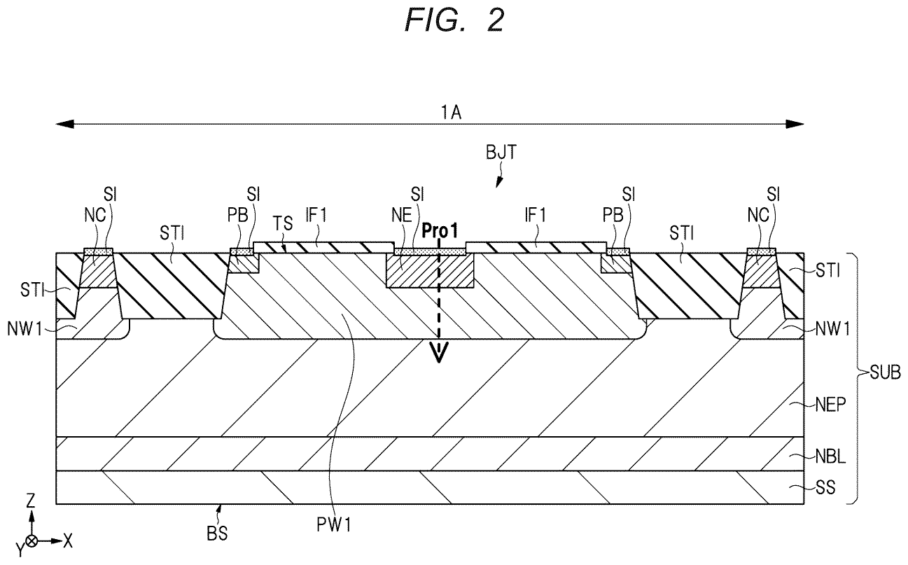

A semiconductor device in the first embodiment includes an NPN type bipolar transistor BJT. The structure of the bipolar transistor BJT will be described using FIGS. 1 and 2. FIG. 1 is a plan view showing the bipolar transistor BJT. FIG. 2 is a cross-sectional view along line A-A shown in FIG. 1.

As shown in FIGS. 1 and 2, the bipolar transistor BJT includes an n-type impurity region NEP, an n-type well region (impurity region) NW1, an n-type collector region (impurity region) NC, a p-type well region (impurity region) PW1, a p-type base region (impurity region) PB, and an n-type emitter region (impurity region) NE.

The impurity region NEP, the well region NW1, and the collector region NC function as the collector of the bipolar transistor BJT. The well region PW1 and the base region PB function as the base of the bipolar transistor BJT. The emitter region NE functions as the emitter of the bipolar transistor BJT.

As shown in FIG. 1, the well region PW1 and the well region NW1 are spaced apart from each other in plan view and are surrounded by the impurity region NEP in plan view. The emitter region NE, the base region PB, and the collector region NC are spaced apart from each other in plan view. The emitter region NE and the base region PB are surrounded by the well region PW1 in plan view. The collector region NC is surrounded by the well region NW1 in plan view. In FIG. 1, the well region PW1 is formed inside the dashed line, and the well region NW1 is formed outside the dotted line.

As shown in FIG. 2, the semiconductor device includes a semiconductor substrate SUB. The impurity region NEP is formed in the semiconductor substrate SUB. The semiconductor substrate SUB of the first embodiment includes, for example, a support substrate SS made of a p-type silicon substrate and the n-type impurity region NEP formed on the support substrate SS. The impurity region NEP is an n-type silicon layer formed on the support substrate SS by epitaxial growth. An n-type buried region (impurity region) NBL is formed across the support substrate SS and the silicon layer.

Note that the semiconductor substrate SUB, which forms a laminated structure including the support substrate SS and the silicon layer, is an example, and the semiconductor substrate SUB may also be a single-layer p-type silicon substrate. In this case, the impurity region NEP and the buried region NBL are formed in the p-type silicon substrate.

The semiconductor substrate SUB has an upper surface TS and a lower surface BS. The impurity region NEP is formed to a predetermined depth from the upper surface TS of the semiconductor substrate SUB. In the impurity region NEP, the well region PW1 and the well region NW1 are formed. The well region PW1 and the well region NW1 are formed from the upper surface TS of the semiconductor substrate SUB to a shallower position than the depth of the impurity region NEP, respectively.

In the well region PW1, the base region PB and the emitter region NE are formed. In the well region NW1, the collector region NC is formed. The emitter region NE, the base region PB, and the collector region NC are disposed at the upper surface TS of the semiconductor substrate SUB, respectively. Specifically, the emitter region NE, the base region PB, and the collector region NC are formed from the upper surface TS of the semiconductor substrate SUB to a shallower position than the depths of the well region PW1 and the well region NW1.

The base region PB has a higher impurity concentration than an impurity concentration of the well region PW1. The well region NW1 has a higher impurity concentration than an impurity concentration of the impurity region NEP. The emitter region NE and the collector region NC have a higher impurity concentration than the impurity concentration of the well region NW1.

Note that although the collector region NC is formed in the well region NW1, if the well region NW1 is not formed, the collector region NC may be formed in the impurity region NEP.

Furthermore, in the semiconductor substrate SUB, an element isolation portion STI is formed. The element isolation portion STI includes a trench formed in the semiconductor substrate SUB to reach a predetermined depth from the upper surface TS of the semiconductor substrate SUB, and an insulating film buried in the trench. The insulating film is, for example, a silicon oxide film.

In the bipolar transistor BJT, the element isolation portion STI is formed in the portion located between the base region PB and the collector region NC (between the well region PW1 and the well region NW1) of the semiconductor substrate SUB.

Note that no insulating film, such as the element isolation portion STI, is formed in the portion of the well region PW1 located between the emitter region NE and the base region PB. In other words, the emitter region NE and the base region PB are disposed so that no insulating film is formed between the emitter region NE and the base region PB.

An insulating film IF1 is selectively formed on a part of the upper surface TS of the semiconductor substrate SUB. The insulating film IF1 is formed on a part of the emitter region NE, on the well region PW1, and on a part of the base region PB, so as to cover a boundary between the emitter region NE and the well region PW1 and to cover a boundary between the well region PW1 and the base region PB. The insulating film IF1 is, for example, a silicon oxide film.

A silicide film SI is formed on the upper surface TS of the semiconductor substrate SUB not covered by the insulating film IF1. That is, the silicide film SI is formed on the base region PB, the emitter region NE, and the collector region NC, which are exposed from the insulating film IF1 and the element isolation portion STI. The silicide film SI may be, for example, a cobalt silicide (Cosi2) film, a nickel silicide (NiSi) film, or a nickel platinum silicide (NiPtSi) film.

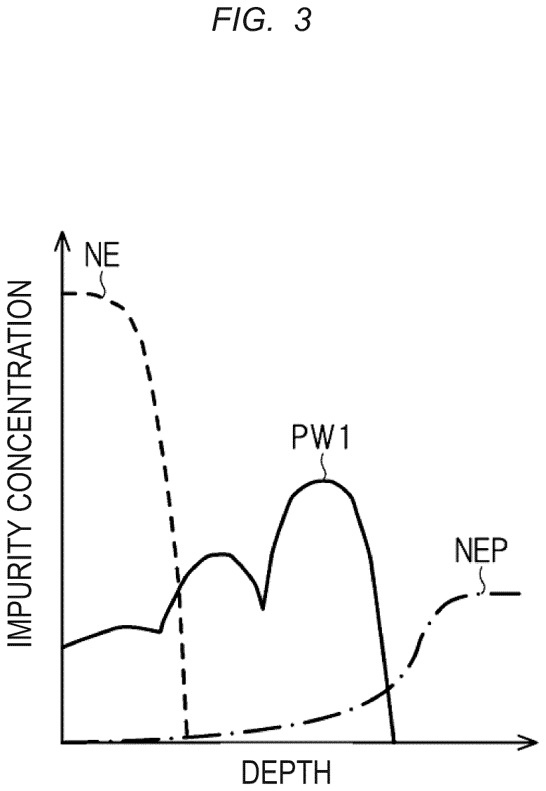

FIG. 3 is a diagram showing an impurity profile of the semiconductor device along the depth direction Pro1 from the upper surface TS of the semiconductor substrate SUB, as shown in FIG. 2. In the first embodiment, the well region PW1 is formed by a plurality of ion implantations with different injection energies. Therefore, as shown in FIG. 3, the concentration in the shallow part of the well region PW1 is reduced, and the concentration in the deep part of the well region PW1 is increased. By increasing the concentration in the deep part of the well region PW1, punch-through can be prevented, and the breakdown voltage between the collector and the base can be secured.

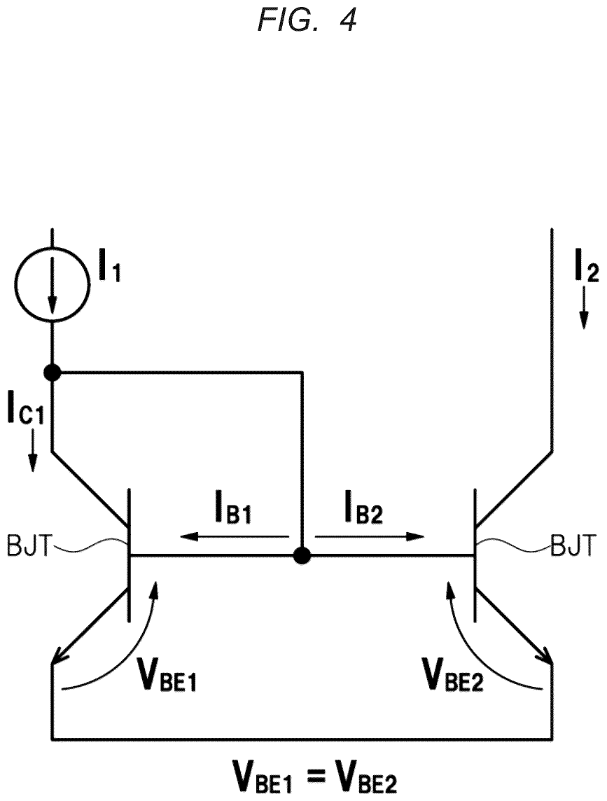

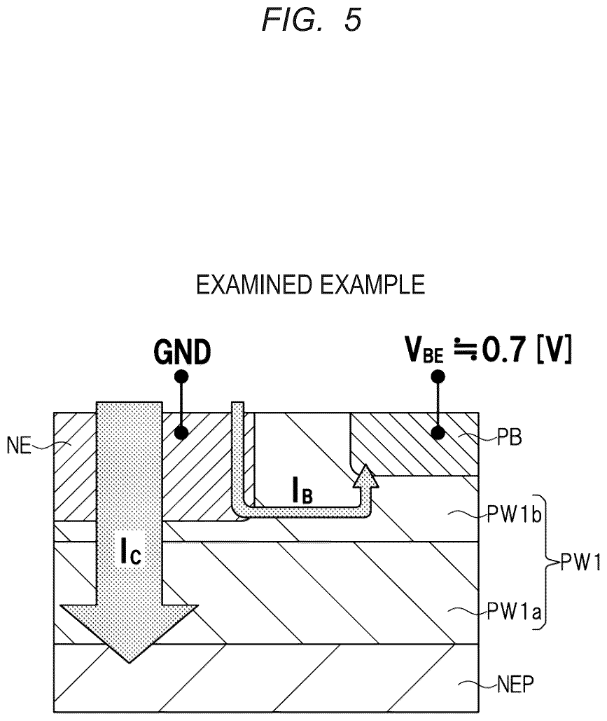

However, due to the reduction in the concentration in the shallow part of the well region PW1, there is a possibility that the base current IB may be likely to increase, and the current amplification factor hFE (=IC/IB), which is the ratio of the base current IB to the collector current IC, may decrease. The following will specifically describe such problems using FIGS. 4 and 5.

FIG. 4 shows a current mirror circuit configured using two bipolar transistors BUT as an example of an analog circuit included in the semiconductor device.

The current mirror circuit is used to flow an appropriate bias current to the transistor in the later stage than the current mirror circuit and to make the transistor in the later stage operate as desired. Therefore, the two bipolar transistors BJT having equal characteristics and sizes are used, and the current I1 and the current I2 flowing through the two bipolar transistors BJT are designed to be equal.

For example, in the bipolar transistor BJT through which the current I1 flows, the voltage VBE1 between the base and the emitter is determined so that the current I1 and the collector current IC1 stabilize in a state where they are almost equal (I1=IC1).

However, precisely, the current I1 indicates the value (I1=IC1−IB1−IB2) subtracted by two base currents IB1, IB2 from the collector current IC1, and an error due to the base currents IB1, IB2 occurs. In normal circuit design, a method of correcting the error due to the base current IB is adopted after determining the collector current IC first. Therefore, an increase in the base currents IB1, IB2 is not preferable in order to increase the current amplification factor hFE (=IC/IB).

The electron current component of the bipolar transistor

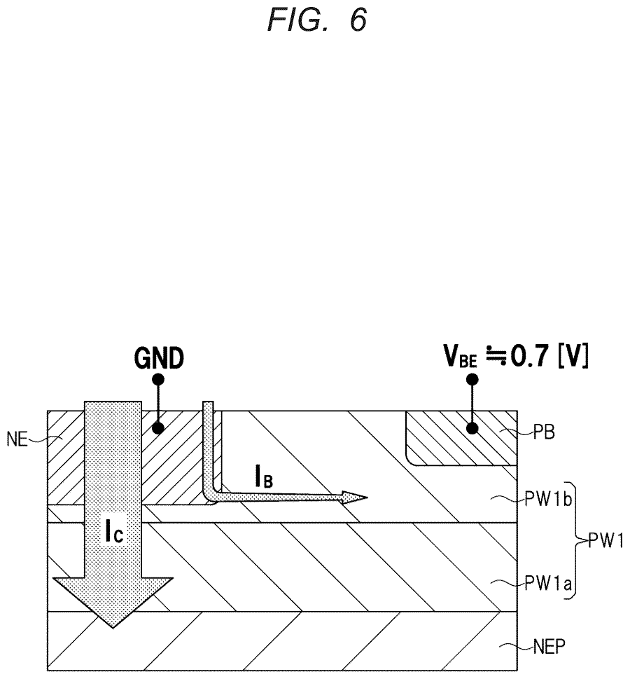

BJT includes components that contribute to the collector current IC and components that contribute to the base current IB. FIGS. 5 and 6 show the flow of electron currents contributing to the collector current IC and the base current IB. FIG. 5 shows a bipolar transistor examined by the present inventors, and FIG. 6 shows the bipolar transistor BJT of the first embodiment.

In FIGS. 5 and 6, the shallow part of the well region PW1 is shown as a low concentration region PW1b, and the deep part of the well region PW1 located under the low concentration region PW1b is shown as a high concentration region PW1a. The emitter region NE and the base region PB are formed in the low concentration region PW1b.

Since the impurity concentration of the low concentration region PW1b is lower than the impurity concentration of the high concentration region PW1a, a part of the electrons contributing to the collector current IC is easily injected towards the base region PB near the location where the lower surface and the side surface of the emitter region NE intersect (the corner of the emitter region NE).

As shown in FIG. 5, in the examined example, since the electron current from the emitter region NE reaches the base region PB, the base current IB increases and the current amplification factor hFE decreases. As shown in FIG. 6, the first embodiment prevents the electron current from the emitter region NE from reaching the base region PB.

For instance, if the impurity concentration in the low concentration region PW1b in FIG. 5 and in FIG. 6 are the same, the distance between the emitter region NE and the base region PB in FIG. 6 is designed to be longer than that in FIG. 5. In FIG. 6, electrons injected from the corner of the emitter region NE flow towards the base region PB to a certain extent but recombine in the low concentration region PW1b located between the emitter region NE and the base region PB. Therefore, the increase in base current IB is suppressed, and the decrease in current amplification factor hFE is also suppressed.

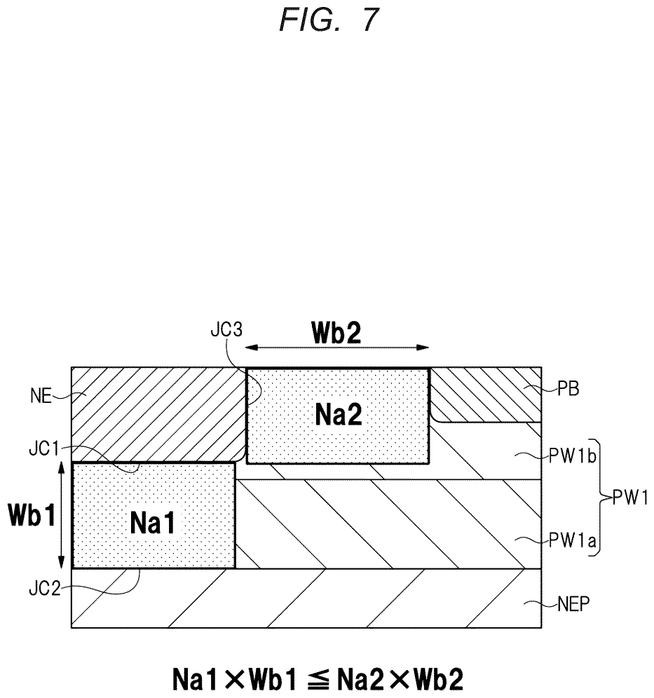

Note that FIG. 6 is an example of a method to suppress the increase in the base current IB, and the conditions that can suppress the increase in base current IB are not limited to the distance between the emitter region NE and the base region PB. The conditions that can suppress the increase in base current IB will be described using FIG. 7 below.

The electron current Jn is calculated by the following equation. “Na” is the impurity concentration in the well region PW1. “Wb” is the distance of the well region PW1. “q” is the elementary charge. “Dn” is the diffusion coefficient of electrons. “ni” is the intrinsic carrier concentration. “k” is the Boltzmann constant. “T” is the absolute temperature.

$$Jn = \frac{- {qD}_{n} {n}_{i}^{2} exp ( \frac{{qV}_{BE}}{kT} )}{Na \times W b} \qquad [ Equation 1 ]$$

The electron current Jn is inversely proportional to the impurity concentration of the well region PW1 per unit area (Na×Wb). When calculating the electron current component contributing to the collector current IC, the distance from a junction surface JC1 between the lower surface of the emitter region NE and the well region PW1 to a junction surface JC2 between the lower surface of the well region PW1 and the impurity region NEP is Wb1, and the impurity concentration in the well region PW1 located under the junction surface JC1 is Na1.

When calculating the electron current component contributing to the base current IB, the distance from a junction surface JC3 between the side surface of the emitter region NE and the well region PW1 to the base region PB is Wb2, and the impurity concentration in the well region PW1 located between the junction surface JC3 and the base region PB is Na2.

The smaller the value of Na1×Wb1, the more the collector current IC can be increased, and the larger the value of Na2×Wb2, the more the base current IB can be decreased. Therefore, to decrease the base current IB and increase the current amplification factor hFE, it is preferable that the relationship (Na1×Wb1)≤(Na2×Wb2) is satisfied, as shown in the “conditions” in FIG. 7. This allows for the improvement of the performance of the bipolar transistor BJT and the enhancement of the performance of the semiconductor device.

For instance, in the case of the well region PW1 that includes the high concentration region PW1a and the low concentration region PW1b as in the first embodiment, since the impurity concentration Na2 is lower than the impurity concentration Na1, it is preferable that the distance Wb2 is longer than the distance Wb1 so as to satisfy the relationship (Na1×Wb1)≤(Na2×Wb2).

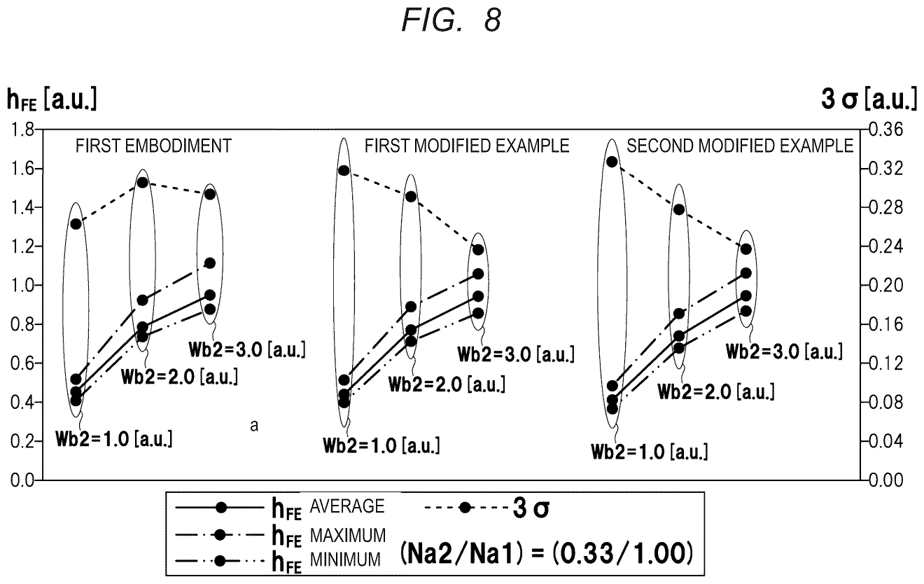

FIG. 8 shows the results of experiments conducted by the present inventors, showing the relationship between the distance Wb2 and the current amplification factor hFE. Furthermore, FIG. 8 also shows the relationship between the distance Wb2 and the variation (3σ) in the impurity concentration included in the low concentration region PW1b. Note that the data in FIG. corresponds to the case where the relationship (Na2/Na1)=(0.33/1.00) is satisfied.

As shown in FIG. 8, when the value of Na2/Na1 is constant, it was found that increasing the distance Wb2 increases the current amplification factor hFE. Moreover, in the first embodiment, the variation (3σ) in the impurity concentration does not change much with the change in distance Wb2, but in the first modified example and the second modified example described later, the variation (3σ) in the impurity concentration is improved with the change in distance Wb2.

### Structure of Low Breakdown Voltage MISFET and High Breakdown Voltage MISFET

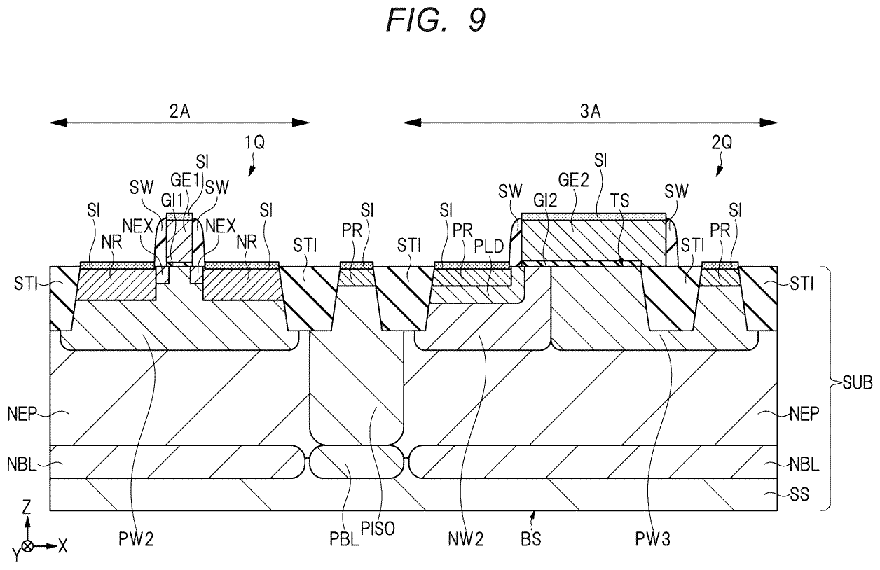

The structure of an n-type low breakdown voltage MISFET 1Q and a p-type high breakdown voltage MISFET 2Q included in the semiconductor device will be described below using FIG. 9.

As shown in FIGS. 2 and 9, the semiconductor device includes a region 1A where the bipolar transistor BJT is formed, a region 2A where the low breakdown voltage MISFET 1Q is formed, and a region 3A where the high breakdown voltage MISFET 2Q is formed. The low breakdown voltage MISFET 1Q is used, for example, in logic circuits. The high breakdown voltage MISFET 2Q has a higher breakdown voltage than the low breakdown voltage MISFET 1Q, is referred to as LDMOSFET (Laterally Diffused Metal Oxide Semiconductor Field Effect Transistor), and is used, for example, in analog circuits or I/O circuits.

As shown in FIG. 9, the n-type buried region NBL and a p-type buried region (impurity region) PBL are formed in the semiconductor substrate SUB. A p-type isolation region (impurity region) PISO is formed in the semiconductor substrate SUB and is located over the buried region PBL. The buried region NBL, the buried region PBL, and the isolation region PISO electrically isolate the semiconductor element such as the bipolar transistor BJT, the low breakdown voltage MISFET 1Q, and the high breakdown voltage MISFET 2Q from each other and electrically isolate them from the p-type support substrate SS.

First, the structure of the low breakdown voltage MISFET 1Q in the region 2A will be described.

The low breakdown voltage MISFET 1Q includes a p-type well region (impurity region) PW2, an n-type extension region (impurity region) NEX, an n-type high concentration diffusion region (impurity region) NR, a gate insulating film GI1, a gate electrode GE1, a sidewall spacer SW, and the silicide film SI.

In a portion of the semiconductor substrate SUB located in the region 2A, the well region PW2 is formed. In the well region PW2, an n-type source region and an n-type drain region are formed. The n-type source region and the n-type drain region each include the extension region NEX, and the high concentration diffusion region NR formed in the well region PW2. The high concentration diffusion region NR has an impurity concentration higher than an impurity concentration of the extension region NEX.

The gate insulating film GI1 is formed on the well region PW2. The gate insulating film GI1 is, for example, a silicon oxide film. The gate electrode GE1 is formed on the gate insulating film GI1. The gate electrode GE1 is, for example, an n-type polycrystalline silicon film.

The sidewall spacer SW is formed on a side surface of the gate electrode GE1. The sidewall spacer SW includes, for example, a silicon oxide film and a silicon nitride film formed on the silicon oxide film. The extension region NEX is covered by the sidewall spacer SW. The silicide film SI is formed on the upper surface of each of the gate electrode GE1 and the high concentration diffusion region NR, which are exposed from the sidewall spacer SW and the element isolation portion STI.

The gate electrode GE1 is formed on a part of the semiconductor substrate SUB located between two extension regions NEX in the X direction. The part of the well region PW2 that is located between a pair of extension regions NEX and located under the gate electrode GE1 functions as the channel region of the low breakdown voltage MISFET 1Q.

Moreover, the well region PW1 of the bipolar transistor BJT and the well region PW2 of the low breakdown voltage MISFET 1Q are formed in the same step. Therefore, the impurity profile of the well region PW2 is the same as the impurity profile of the well region PW1 shown in FIG. 3. Note that “having the same impurity profile” means that the impurity profiles are the same in the range of errors due to manufacturing variations. That is, the deep part of the well region PW2 is a high concentration region similar to the high concentration region PW1a of the well region PW1, and the shallow part of the well region PW2 is a low concentration region similar to the low concentration region PW1b. The impurity concentration of the high concentration region of the well region PW2 is higher than the impurity concentration of the low concentration region of the well region PW2.

In the low breakdown voltage MISFET 1Q, since the impurity concentration of the shallow part of the well region PW2 is lower than the impurity concentration of the deep part of the well region PW2, latch-up can be suppressed. Therefore, the reliability of the low breakdown voltage MISFET 1Q can be secured, which secures the reliability of the semiconductor device. Moreover, since the well region PW1 and the well region PW2 can be formed in the same step, the manufacturing step can be simplified, and an increase in manufacturing costs can be suppressed.

Next, the structure of the high breakdown voltage MISFET 2Q in the region 3A will be described.

The high breakdown voltage MISFET 2Q includes a p-type well region (impurity region) PW3, an n-type well region (impurity region) NW2, a p-type low concentration diffusion region (impurity region) PLD, a p-type high concentration diffusion region (impurity region) PR, a gate insulating film GI2, a gate electrode GE2, the sidewall spacer SW, and the silicide film SI.

In a portion of the semiconductor substrate SUB located in the region 3A, the well region PW3 and the well region NW2 are formed. In the well region PW3, the high concentration diffusion region PR is formed. The drain region of the high breakdown voltage MISFET 2Q includes the well region PW3 and the high concentration diffusion region PR.

In the well region NW2, a p-type source region is formed. The p-type source region includes the low concentration diffusion region PLD formed in the well region NW2, and the high concentration diffusion region PR formed in the low concentration diffusion region PLD. The low concentration diffusion region PLD has a higher impurity concentration than an impurity concentration of the well region PW3 and lower than an impurity concentration of the high concentration diffusion region PR.

The gate insulating film GI2 is formed on the well region PW3 and the well region NW2. The gate insulating film GI2, for example, is a silicon oxide film and has a greater thickness than a thickness of the gate insulating film GI1. The gate electrode GE2 is formed on the gate insulating film GI2. The gate electrode GE2, for example, is a p-type polycrystalline silicon film.

Also, the element isolation portion STI is formed in the well region PW3. The well region PW3 is formed deeper than the depth of the element isolation portion STI. Among the two side surfaces of the gate electrode GE2, the side surface facing the high concentration diffusion region PR, which configures the drain region, is located on the element isolation portion STI.

On the side surface of the gate electrode GE2, the sidewall spacer SW is formed. The silicide film SI is formed on the upper surface of each of the gate electrode GE2 and the high concentration diffusion region PR which are exposed from the sidewall spacer SW and the element isolation portion STI.

The portion of the well region NW2 located between the low concentration diffusion region PLD and the well region PW3 and located under the gate electrode GE2 functions as the channel region of the high breakdown voltage MISFET 2Q.

### Manufacturing Method of Semiconductor Device

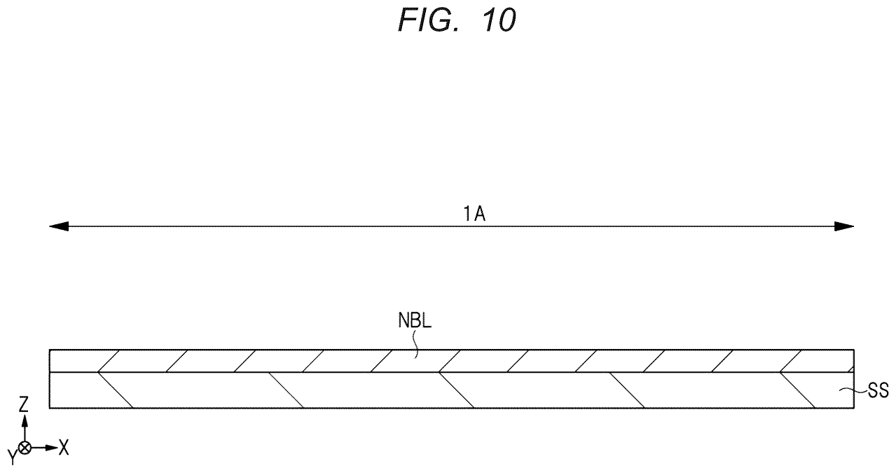

The following describes each manufacturing step included in the manufacturing method of the semiconductor device in the first embodiment, using FIGS. 10 to 23. Note that FIGS. 10, 12, 14, 16, 18, 20, and 22 correspond to the cross-sectional views along the line A-A shown in FIG. 1.

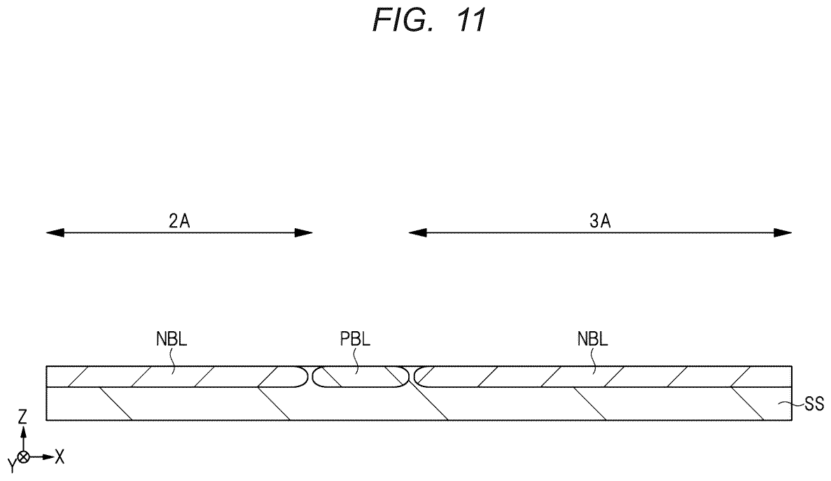

As shown in FIGS. 10 and 11, first, the support substrate SS made of p-type silicon is prepared. Next, using photolithography techniques and ion implantation, the n-type buried region NBL and the p-type buried region PBL are sequentially and selectively formed in the support substrate SS. After forming the impurity region NEP on the support substrate SS, the buried region NBL and the buried region PBL may also be formed using photolithography techniques and ion implantation.

Next, by performing heat treatment, the impurities contained in the buried region NBL and the buried region PBL are diffused. This heat treatment is carried out in an inert gas atmosphere, for example, at a temperature range of 950 degrees Celsius or higher and 1250 degrees Celsius or lower, and for a time of 60 minutes or more and 120 minutes or less.

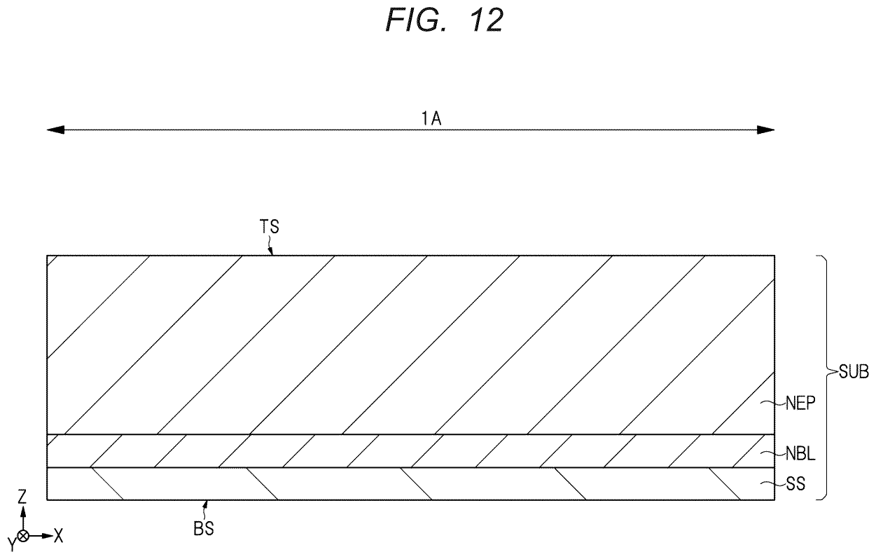

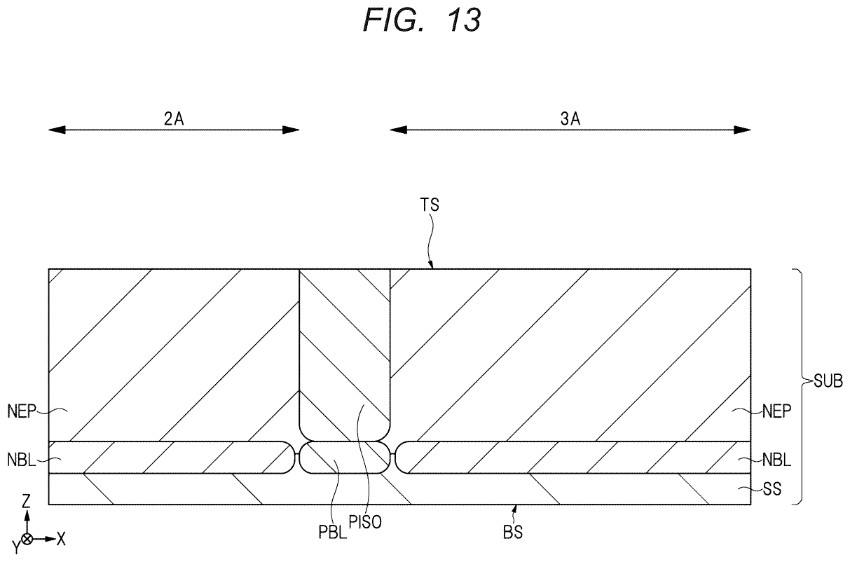

As shown in FIGS. 12 and 13, first, the n-type impurity region NEP, which is a silicon layer, is formed on the support substrate SS by epitaxial growth. Thus, the semiconductor substrate SUB including the support substrate SS and the impurity region NEP is prepared.

The semiconductor substrate SUB may also be a single layer of p-type silicon substrate. In this case, after preparing a p-type silicon substrate, the buried region PBL, the buried region NBL, and the impurity region NEP are sequentially formed in the p-type silicon substrate by photolithography techniques and ion implantation. In this way, the semiconductor substrate SUB including the impurity region NEP may be prepared.

Next, by photolithography techniques and ion implantation, the p-type isolation region PISO is selectively formed in the impurity region NEP and on the buried region PBL. Then, by performing a heat treatment, the impurities contained in the isolation region PISO are diffused. This heat treatment is carried out in an inert gas atmosphere, for example, at a temperature range of 950 degrees Celsius or higher and 1250 degrees Celsius or lower, and for a time of 60 minutes or more and 120 minutes or less.

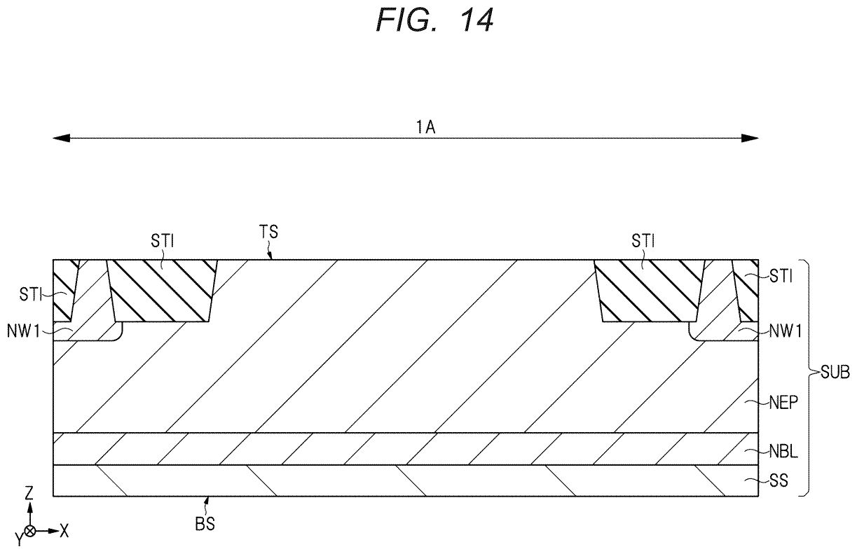

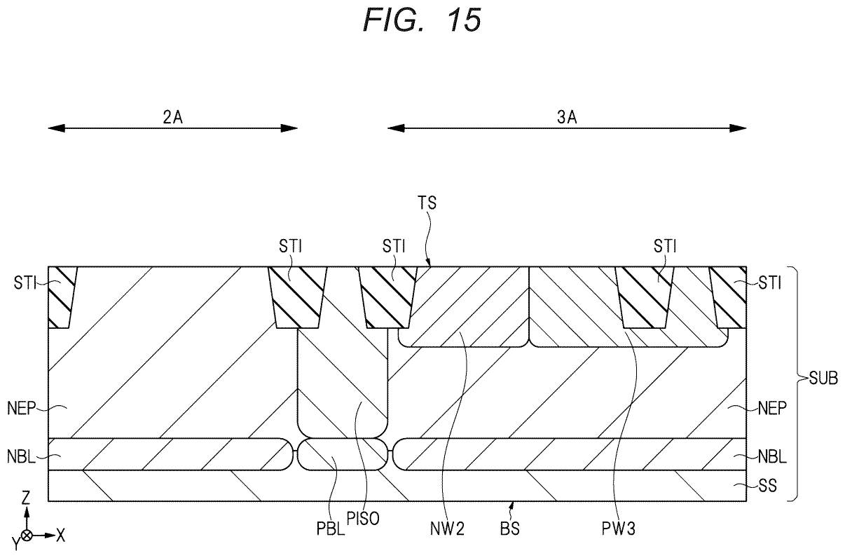

As shown in FIGS. 14 and 15, in the semiconductor substrate SUB, the element isolation region STI, the n-type well region NW1, the n-type well region NW2, and the p-type well region PW3 are formed.

First, trenches are formed in the semiconductor substrate

SUB by photolithography technology and anisotropic etching treatment to reach a predetermined depth from the upper surface of the semiconductor substrate SUB. Next, an insulating film such as a silicon oxide film is formed on the semiconductor substrate SUB so as to fill the inside of the trenches. Then, the insulating film located outside the trenches is removed by polishing using the CMP method, so that the insulating film buried inside the trenches remains. In this way, the element isolation region STI includes the trenches and the insulating film is formed.

Next, by photolithography technology and ion implantation, the well region NW1 is selectively formed in the impurity region NEP in the region 1A, and the well regions NW2 and the well region PW3 are sequentially and selectively formed in the impurity region NEP in the region 3A.

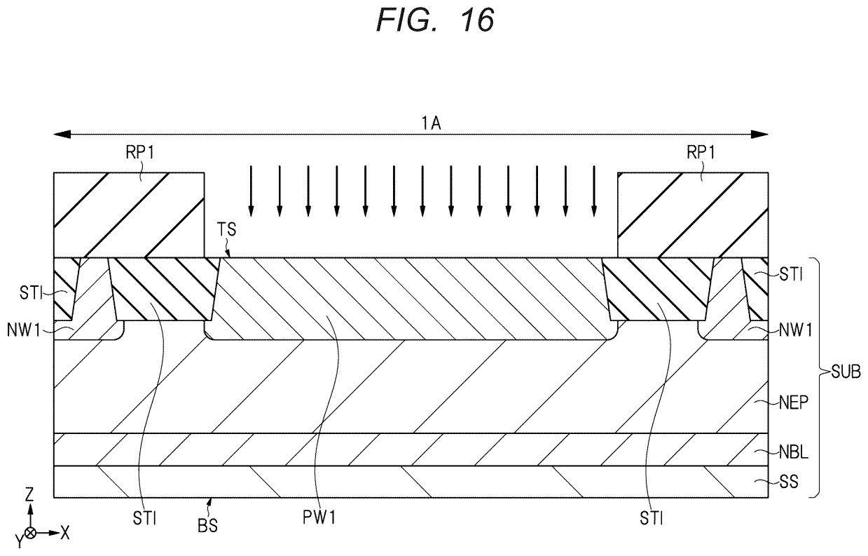

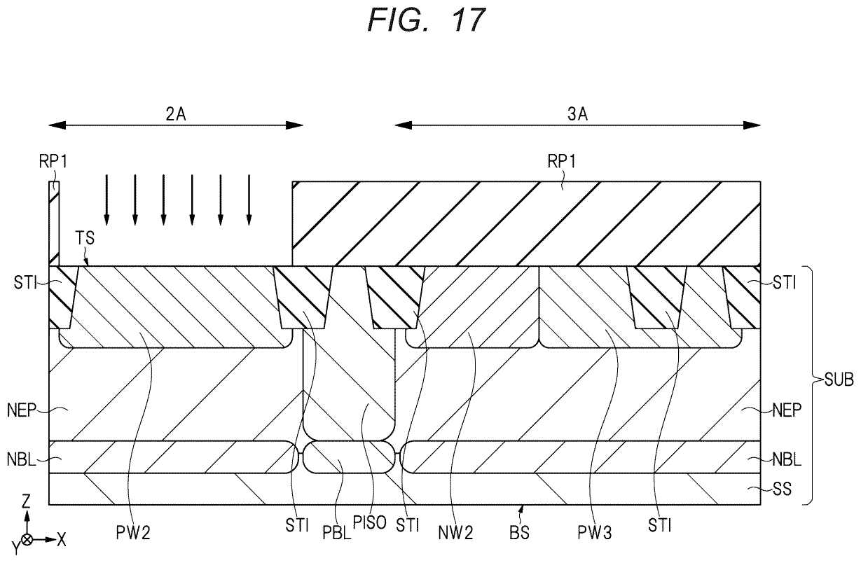

As shown in FIGS. 16 and 17, the p-type well region PW1 and the p-type well region PW2 are formed in the semiconductor substrate SUB.

First, a resist pattern RP1 is formed on the upper surface TS of the semiconductor substrate SUB to selectively open a part of the impurity region NEP located in the region 1A and the region 2A. Next, by using the resist pattern RP1 as a mask for ion implantation, the well region PW1 is formed in the impurity region NEP located in the region 1A, and the well region PW2 is formed in the impurity region NEP located in the region 2A. Then, the resist pattern RP1 is removed by ashing.

Note that the well region PW1 and the well region PW2 are formed by a plurality of ion implantations with different injection energies. Therefore, the well region PW1 and the well region PW2 have an impurity profile as shown in FIG. 3.

Moreover, a step of forming the well region PW1 and the well region PW2, the step of forming the well region PW3, the step of forming the well region NW1, and the step of forming the well region NW2 may be performed in any order.

Next, a heat treatment is performed to activate the impurities contained in the well region PW1, the well region PW2, the well region PW3, the well region NW1, and the well region NW2. This heat treatment is performed in an inert gas atmosphere, for example, at a temperature range of 900 degrees Celsius or higher and 1000 degrees Celsius or lower, and for a duration of 10 seconds or more and 60 seconds or less.

Furthermore, since this heat treatment is performed for a shorter duration than the heat treatment for diffusing impurities contained in the buried region NBL, the buried region PBL, and the isolation region PISO, the impurity profiles of each of the well region PW1, the well region PW2, the well region PW3, the well region NW1, and the well region NW2 remain almost unchanged, nearly identical to those at the time of ion implantation.

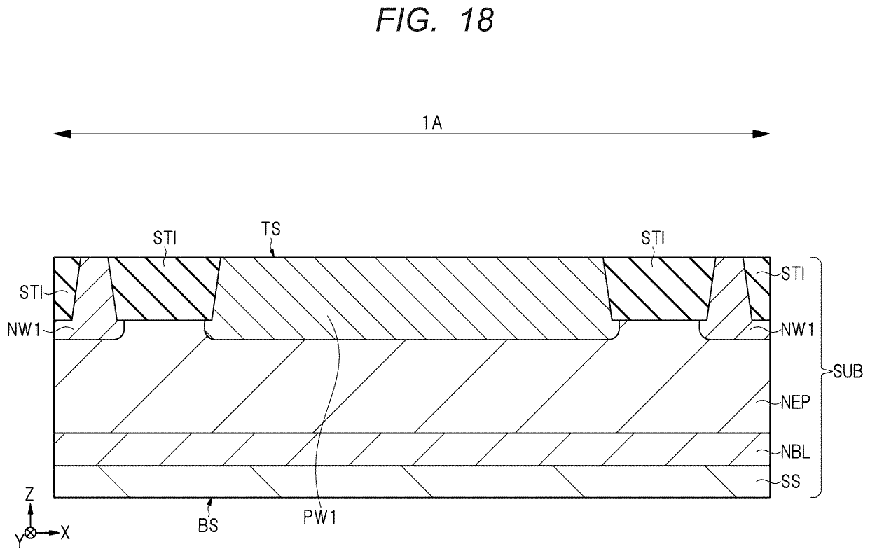

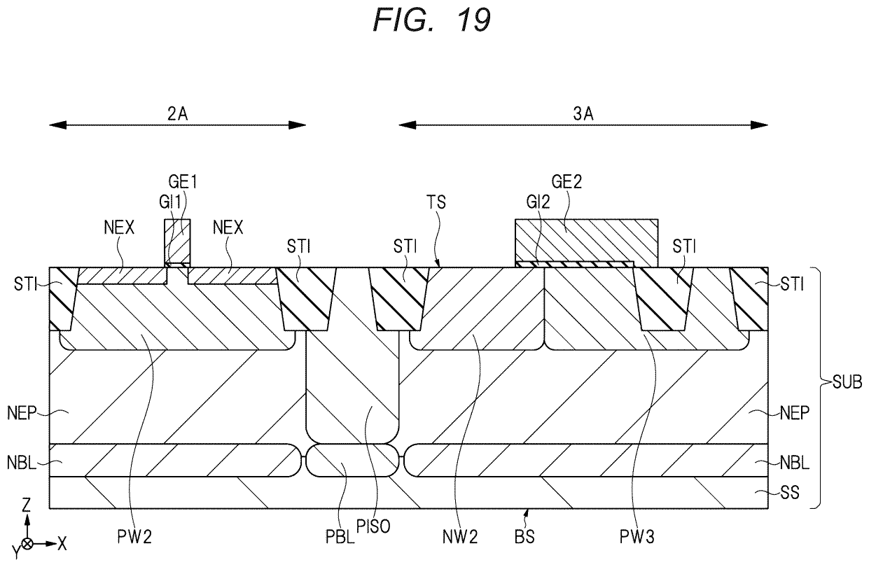

As shown in FIGS. 18 and 19, the gate insulating film GI1, the gate insulating film GI2, the gate electrode GE1, and the gate electrode GE2 are formed on the upper surface TS of the semiconductor substrate SUB, and the n-type extension region NEX is formed in the semiconductor substrate SUB.

First, in the region 1A, the region 2A, and the region 3A, the gate insulating film GI2 is formed on the upper surface TS of the semiconductor substrate SUB exposed from the element isolation portion STI, for example, by thermal oxidation. Then, the gate insulating film GI2 located in the region 1A and the region 2A is selectively removed by photolithography techniques and isotropic etching. As a result, the gate insulating film GI2 remains on the well regions NW2 and the well region PW3 in the region 3A.

Next, in the region 1A and the region 2A, the gate insulating film GI1 is formed on the upper surface TS of the semiconductor substrate SUB exposed from the element isolation portion STI, for example, by thermal oxidation. Then, for example, by a film formation step using the CVD method, a polycrystalline silicon film is formed on the gate insulating film GI1 and the gate insulating film GI2. Next, by photolithography techniques and ion implantation, n-type impurities are selectively introduced into the polycrystalline silicon film located in the region 2A, and p-type impurities are selectively introduced into the polycrystalline silicon film located in the region 3A.

Next, the polycrystalline silicon film is patterned by photolithography techniques and anisotropic etching. Accordingly, the polycrystalline silicon film located in the region 1A is removed, the gate electrode GE1 is formed from the n-type polycrystalline silicon film located in the region 2A, and the gate electrode GE2 is formed from the p-type polycrystalline silicon film located in the region 3A. Next, it may be possible to remove the gate insulating film GI1 and the gate insulating film GI2 exposed from the gate electrode GE1 and the gate electrode GE2 by isotropic etching treatment.

Thus, in the region 2A, the gate insulating film GI1 is formed on the well region PW2, and the gate electrode GE1 is formed on the gate insulating film GI1. Also, in the region 3A, the gate insulating film GI2 is formed on the well region NW2 and the well region PW3, and the gate electrode GE2 is formed on the gate insulating film GI2.

Next, by photolithography techniques and ion implantation, the n-type extension region NEX is selectively formed in the well region PW2.

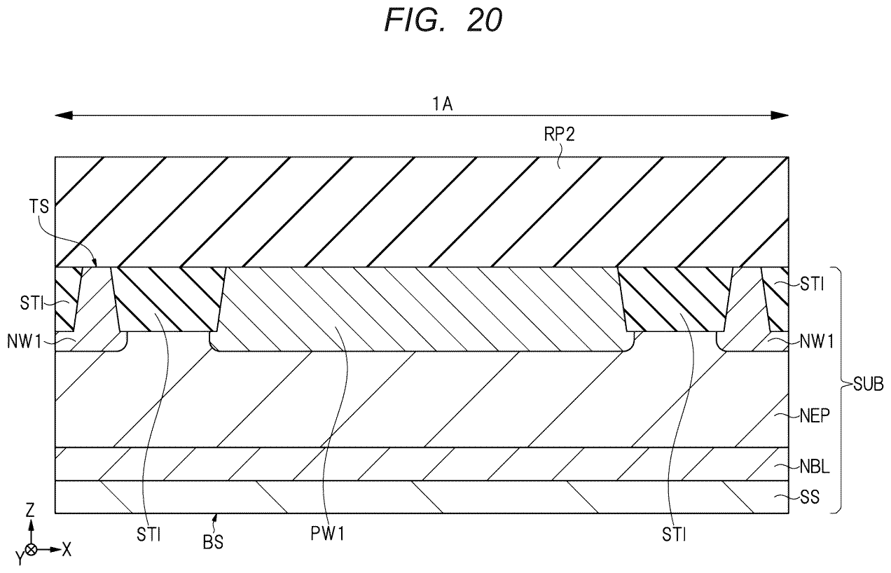

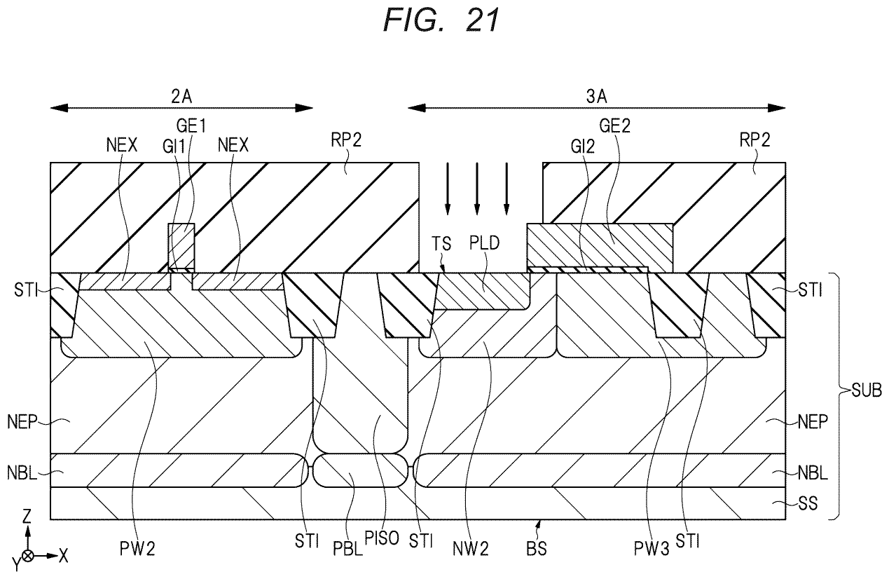

As shown in FIGS. 20 and 21, the p-type low concentration diffusion region PLD is formed in the semiconductor substrate SUB.

First, a resist pattern RP2 selectively opening the well region NW2 is formed on the upper surface TS of the semiconductor substrate SUB and on the gate electrode GE2. Next, by using the resist pattern RP2 as a mask for ion implantation, the low concentration diffusion region PLD is formed in the well region NW2 exposed from the gate electrode GE2 in the region 3A. Next, the resist pattern RP2 is removed by ashing treatment.

It may be performed in any order whether the step of forming the extension region NEX or the step of forming the low concentration diffusion region PLD.

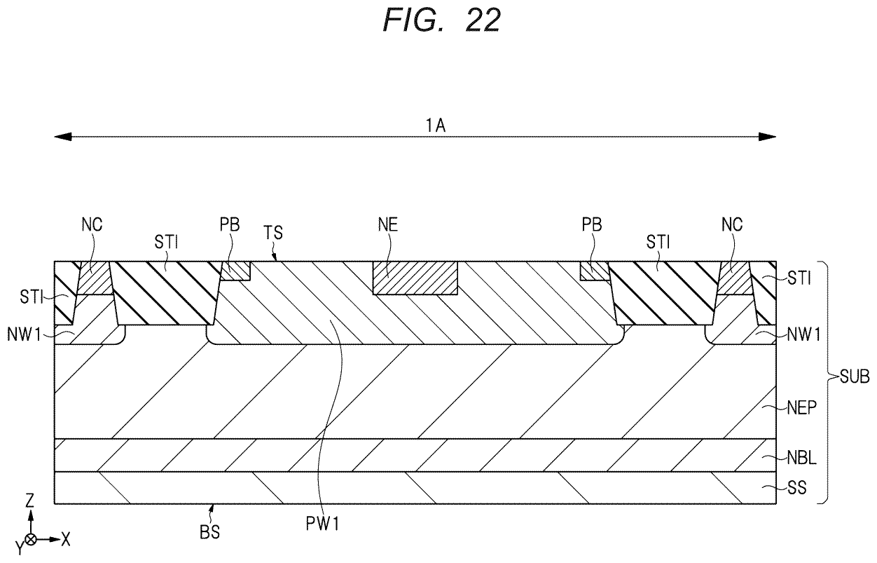

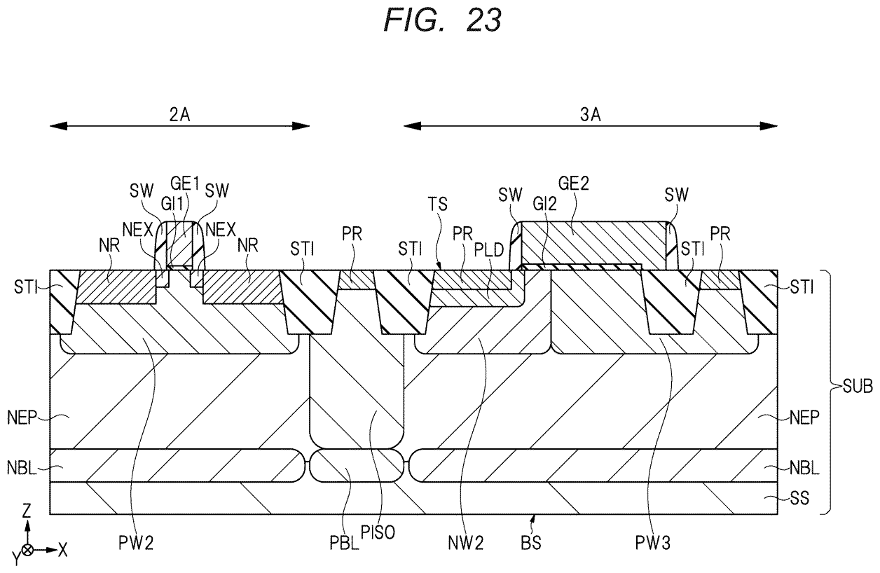

As shown in FIGS. 22 and 23, the sidewall spacer SW is formed on each side surface of the gate electrode GE1 and the gate electrode GE2. In the semiconductor substrate SUB, the p-type high concentration diffusion region PR and the p-type base region PB are formed in the same step, and in the semiconductor substrate SUB, the n-type high concentration diffusion region NR, the n-type emitter region NE, and the n-type collector region NC are formed in the same step.

First, for example, a laminated film including an oxide silicon film and a nitride silicon film is formed on the semiconductor substrate SUB to cover the gate electrode GE1 and the gate electrode GE2, by a film formation step using, for example, the CVD method. Next, by performing anisotropic etching on the laminated film, the sidewall spacer SW is formed from the laminated film remaining on each side surface of the gate electrode GE1 and the gate electrode GE2.

Next, by photolithography techniques and ion implantation, the base region PB is selectively formed in the well region PW1 in the region 1A, the high concentration diffusion region PR is selectively formed in the well region NW3 and the low concentration diffusion region PLD in the region 3A, and the high concentration diffusion region PR is selectively formed in the isolation region PISO.

Next, by photolithography techniques and ion implantation, the emitter region NE is selectively formed in the well region PW1 in the region 1A, the collector region NC is selectively formed in the well region NW1 in the region 1A, and the high concentration diffusion region NR is selectively formed in the well region PW2 in the region 2A.

It should be noted that the step of forming the high concentration diffusion region PR and the base region PB, and the step of forming the high concentration diffusion region NR, the emitter region NE, and the collector region NC may be performed in any order.

Next, by performing a heat treatment, impurities contained in the low concentration diffusion region PLD, the high concentration diffusion region PR, the base region PB, the extension region NEX, the high concentration diffusion region NR, the emitter region NE, and the collector region NC are activated. This heat treatment is performed in an inert gas atmosphere, for example, at a temperature range of 900 degrees Celsius or more and 1000 degrees Celsius or less, and for a time of 10 seconds or more and 60 seconds or less.

Thereafter, through the following steps, the semiconductor device shown in FIGS. 2 and 9 is manufactured.

First, the insulating film IF1 is formed on the upper surface TS of the semiconductor substrate SUB to cover the gate electrode GE1, the gate electrode GE2, and the sidewall spacer SW, by a film formation step using, for example, the CVD method. Next, the insulating film IF1 is patterned by photolithography techniques and anisotropic etching. As a result, the insulating film IF1 remains on a part of the emitter region NE, on the well region PW1, and on a part of the base region PB so as to cover the boundary between the emitter region NE and the well region PW1, and the boundary between the well region PW1 and the base region PB.

Next, by salicide technology, the silicide film SI is formed on the base region PB, the emitter region NE, the collector region NC, the gate electrode GE1, the gate electrode GE2, the high concentration diffusion region PR, and the high concentration diffusion region NR, exposed from the insulating film IF1 and the element isolation portion STI.

### First Modified Example

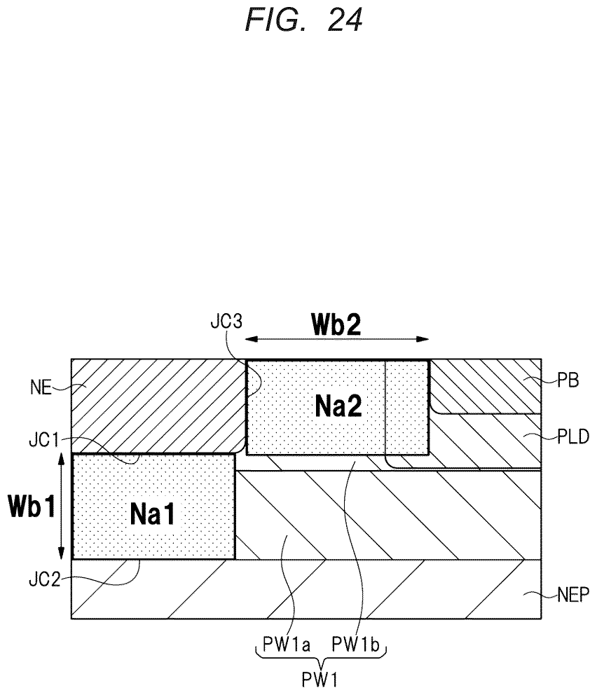

The semiconductor device in the first modified example of the first embodiment is described below using FIG. 24. It should be noted that in the following description, the differences from first embodiment are mainly described, and the points overlapping with first embodiment are omitted.

As shown in FIG. 24, in the first modified example, the low concentration diffusion region PLD is formed in the well region PW1. The low concentration diffusion region PLD of the bipolar transistor BJT and the low concentration diffusion region PLD of the high breakdown voltage MISFET 2Q are formed in the same step. For this purpose, in FIG. 20, an opening is formed in the resist pattern RP2 formed in the region 1A to expose a part of the well region PW1.

The impurity profile of the low concentration diffusion region PLD located in the region 1A is the same as the impurity profile of the low concentration diffusion region PLD located in the region 3A. The low concentration diffusion region PLD located in the region 1A has an impurity concentration higher than the impurity concentration of the well region PW1 and lower than the impurity concentration of the base region PB. The base region PB is formed in the low concentration diffusion region PLD. Furthermore, in plan view, the low concentration diffusion region PLD, the emitter region NE, and the collector region NC located in the region 1A are spaced apart from each other.

In the first modified example, the impurity concentration Na2 includes the impurity concentration of the low concentration diffusion region PLD located between the junction surface JC3 and the base region PB. Therefore, in the first modified example, the impurity concentration Na2 becomes higher than in the first embodiment, making it easier to satisfy the relationship (Na1×Wb1)≤(Na2×Wb2). Consequently, in the first modified example, it is easier to reduce the base current IB and increase the current amplification factor hFE than in the first embodiment.

As shown in FIG. 8, when the value of Na2/Na1 is constant, it was found that in the first modified example, increasing the distance Wb2 increases the current amplification factor hFE. Also, in the first modified example, by forming the low concentration diffusion region PLD in the well region PW1, the variation (3σ) in the impurity concentration contained in the low concentration region PW1b with respect to changes in distance Wb2 is improved.

Furthermore, in the first modified example, since the impurity concentration Na2 becomes higher, it is possible to shorten the distance Wb2 in the range where the relationship (Na1×Wb1)≤(Na2×Wb2) is satisfied. In this case, the planar area of the bipolar transistor BJT can be reduced, enabling the miniaturization of the semiconductor device.

Moreover, since the low concentration diffusion region PLD located in the region 1A and the low concentration diffusion region PLD located in the region 3A can be formed by the same step, the manufacturing step can be simplified, and an increase in manufacturing costs can be suppressed.

### Second Modified Example

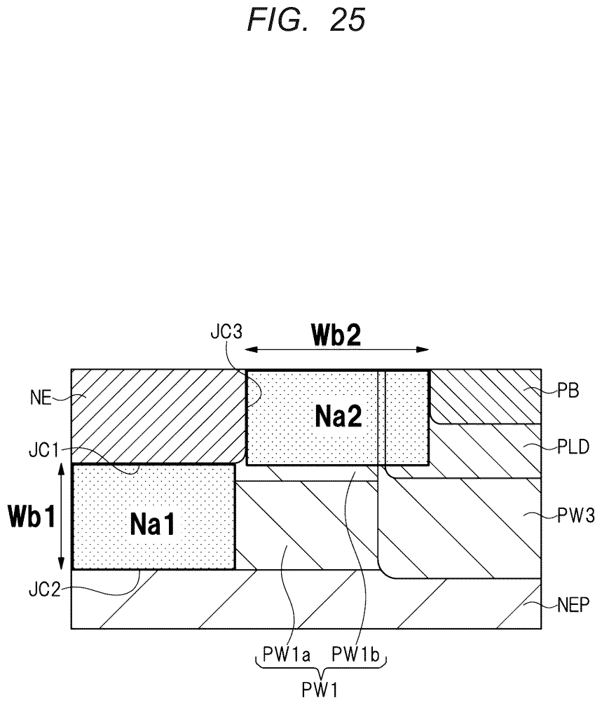

The semiconductor device in the second modified example of the first embodiment is described below using FIG. 25. The following description mainly addresses the differences from the first modified example, and the description of points overlapping with the first modified example is omitted.

As shown in FIG. 24, in the second modified example, not only the low concentration diffusion region PLD but also the well region PW3 is formed in the well region PW1. The well region PW3 of the bipolar transistor BJT and the well region PW3 of the high breakdown voltage MISFET 2Q are formed in the same step.

The impurity profile of the well region PW3 located in the region 1A is the same as the impurity profile of the well region PW3 located in the region 3A. The well region PW3 located in the region 1A has an impurity concentration lower than the impurity concentrations of the low concentration diffusion region PLD and the base region PB. The base region PB and the low concentration diffusion region PLD are formed in the well region PW3. Also, in plan view, the well region PW3, the emitter region NE, and the collector region NC located in the region 1A are spaced apart from each other.

In the second modified example, the impurity concentration Na2 includes the impurity concentration of the low concentration diffusion region PLD located between the junction surface JC3 and the base region PB, and the impurity concentration of the well region PW3. Therefore, in the second modified example, the impurity concentration Na2 becomes higher than the impurity concentration Na2 in the first embodiment, making it easier to satisfy the relationship (Na1×Wb1)≤(Na2×Wb2). Therefore, in the second modified example, it is easier to reduce the base current IB and to increase the current amplification factor hFE than in the first embodiment.

As shown in FIG. 8, when the value of Na2/Na1 is constant, it was found that in the second modified example, by increasing the distance Wb2, the current amplification factor hFE can be increased. Furthermore, in the second modified example, by forming the low concentration diffusion region PLD and the well region PW3 in the well region PW1, the variation (3σ) of impurity concentration with respect to the change in distance Wb2 is improved.

Similarly to the first modified example, in the second modified example, since the impurity concentration Na2 increases, it is also possible to shorten the distance Wb2 in the range that satisfies the relationship (Na1×Wb1)≤(Na2×Wb2). In this case, since the planar area of the bipolar transistor BJT can be reduced, it is possible to achieve miniaturization of the semiconductor device.

Moreover, since the well region PW3 located in the region 1A and the well region PW3 located in the region 3A can be formed by the same manufacturing step, the manufacturing step can be simplified, and the increase in manufacturing cost can be suppressed.

Although the present invention has been specifically described based on the embodiments, the present invention is not limited to these embodiments, and various modifications can be made without departing from the gist thereof.

What is claimed is:

1. A semiconductor device comprising:
a semiconductor substrate;
a first impurity region of a first conductivity type formed in the semiconductor substrate;
a first well region of a second conductivity type opposite the first conductivity type formed in the first impurity region;
an emitter region of the first conductivity type formed in the first well region;
a base region of the second conductivity type formed in the first well region and having a higher impurity concentration than an impurity concentration of the first well region; and
a collector region of the first conductivity type formed in the first impurity region and having a higher impurity concentration than an impurity concentration of the first impurity region,
wherein the emitter region, the base region, and the collector region are spaced apart from each other in plan view, and
wherein, when a distance from a first junction surface between a lower surface of the emitter region and the first well region to a second junction surface between a lower surface of the first well region and the first impurity region is Wb1, an impurity concentration of a part of the first well region located under the first junction surface is Na1, a distance from a third junction surface between a side surface of the emitter region and the first well region to the base region is Wb2, and an impurity concentration of a part of the first well region located between the third junction surface and the base region is Na2, the semiconductor device satisfy a relationship (Na1×Wb1)≤(Na2×Wb2).

2. The semiconductor device according to claim 1,
wherein the first well region comprises:
a low concentration region; and
a high concentration region located under the low concentration region, and
wherein an impurity concentration of the high concentration region is higher than an impurity concentration of the low concentration region.

3. The semiconductor device according to claim 2,
wherein the emitter region and the base region are formed in the low concentration region.

4. The semiconductor device according to claim 2,
wherein the impurity concentration Na2 is lower than the impurity concentration Na1, and
wherein the distance Wb2 is longer than the distance Wb1.

5. The semiconductor device according to claim 2, comprising:
a second well region of the second conductivity type formed in the semiconductor substrate;
a first gate insulating: film formed on the second well region; and
a first gate electrode formed on the first gate insulating film,
wherein the first impurity region, the first well region, the emitter region, the base region, and the collector region configure a bipolar transistor,
wherein the second well region, the first gate insulating film, and the first gate electrode configure a first MISFET, and
wherein an impurity profile of the first well region is the same as an impurity profile of the second well region.

6. The semiconductor device according to claim 1, comprising:
a second impurity region of the second conductivity type formed in the first well region, the second impurity region having a higher impurity concentration than the impurity concentration of the first well region and having a lower impurity concentration than an impurity concentration of the base region,
wherein the emitter region, the second impurity region, and the collector region are spaced apart from each other in plan view,
wherein the base region is formed in the second impurity region, and
wherein the impurity concentration Na2 includes the impurity concentration of the second impurity region located between the third junction surface and the base region.

7. The semiconductor device according to claim 6, comprising:
a third well region of the first conductivity type formed in the semiconductor substrate;
a third impurity region of the second conductivity type formed in the third well region;
a fourth impurity region of the second conductivity type formed in the third impurity region and having a higher impurity concentration than an impurity concentration of the third impurity region;
a second gate insulating film formed on the third well region; and
a second gate electrode formed on the second gate insulating film,
wherein the first impurity region, the first well region, the emitter region, the base region, and the collector region configure a bipolar transistor,
wherein the third well region, the third impurity region, the fourth impurity region, the second gate insulating film, and the second gate electrode configure a second MISFET, and
wherein an impurity profile of the second impurity region is the same as an impurity profile of the third impurity region.

8. The semiconductor device according to claim 1,
wherein an insulating film is not formed in a part of the first well region located between the emitter region and the base region.

9. The semiconductor device according to claim 1,
wherein the first conductivity type is n-type, and
wherein the second conductivity type is p-type.

10. The semiconductor device according to claim 1,
wherein the base region surrounds the emitter region in plan view, and
wherein the collector region surrounds the base region and the emitter region in plan view.

11. A method of manufacturing a semiconductor device, the method comprising:
(a) preparing a semiconductor substrate comprising a first impurity region of a first conductivity type;
(b) forming a first well region of a second conductivity type opposite the first conductivity type in the first impurity region;
(c) forming a base region of the second conductivity type in the first well region, the base region having a higher impurity concentration than an impurity concentration of the first well region; and
(d) forming an emitter region of the first conductivity type in the first well region, and forming a collector region of the first conductivity type in the first impurity region, the collector region having a higher impurity concentration than an impurity concentration of the first impurity region,
wherein the emitter region, the base region, and the collector region are spaced apart from each other in plan view, and
wherein, when a distance from a first junction surface between a lower surface of the emitter region and the first well region to a second junction surface between a lower surface of the first well region and the first impurity region is Wb1, an impurity concentration of a part of the first well region located under the first junction surface is Na1, a distance from a third junction surface between a side surface of the emitter region and the first well region to the base region is Wb2, and an impurity concentration of a part of the first well region located between the third junction surface and the base region is Na2, the semiconductor device satisfy a relationship (Na1×Wb1)≤(Na2×Wb2).

12. The method according to claim 11,
wherein the first well region is formed by a plurality of ion implantations with different injection energies,
wherein the first well region comprises:
a low concentration region; and
a high concentration region located under the low concentration region, and
wherein an impurity concentration of the high concentration region is higher than an impurity concentration of the low concentration region.

13. The method according to claim 12,
wherein the emitter region and the base region are formed in the low concentration region.

14. The method according to claim 12,
wherein the impurity concentration Na2 is lower than the impurity concentration Na1, and
wherein the distance Wb2 is longer than the distance Wb1.

15. The method according to claim 12, comprising:
(e) forming a second well region of the second conductivity type in the semiconductor substrate;
(f) forming a first gate insulating film on the second well region; and
(g) forming a first gate electrode on the first gate insulating film,
wherein the first impurity region, the first well region, the emitter region, the base region, and the collector region configure a bipolar transistor,
wherein the second well region, the first gate insulating film, and the first gate electrode configure a first MISFET, and
wherein the (b) and the (e) are performed as the same step.

16. The method according to claim 11, comprising:
(h) between the (b) and the (c), forming a second impurity region of the second conductivity type in the first well region,
wherein the base region is formed in the second impurity region,
wherein the second impurity region has a higher impurity concentration than the impurity concentration of the first well region and has a lower impurity concentration than an impurity concentration of the base region,
wherein the emitter region, the second impurity region, and the collector region are spaced apart from each other in plan view,
wherein the impurity concentration Na2 comprises an impurity concentration of the second impurity region located between the third junction surface and the base region.

17. The method according to claim 16, comprising:
(i) forming a third well region of the first conductivity type in the semiconductor substrate;
(j) forming a third impurity region of the second conductivity type in the third well region;
(k) forming a fourth impurity region of the second conductivity type in the third impurity region, the fourth impurity region having a higher impurity concentration than an impurity concentration of the third impurity region;
(l) forming a second gate insulating film on the third well region; and
(m) forming a second gate electrode on the second gate insulating film,
wherein the first impurity region, the first well region, the emitter region, the base region, and the collector region configure a bipolar transistor,
wherein the third well region, the third impurity region, the fourth impurity region, the second gate insulating film, and the second gate electrode configure a second MISFET, and
wherein the (h) and the (j) are performed as the same step.

18. The method according to claim 11,
wherein an insulating film is not formed in a part of the first well region located between the emitter region and the base region.

19. The method according to claim 11,
wherein the first conductivity type is n-type, and
wherein the second conductivity type is p-type.

20. The method according to claim 11,
wherein the base region surrounds the emitter region in plan view, and
wherein the collector region surrounds the base region and the emitter region in plan view.
